(19) United States
(12) Patent Application Publication
(10) Pub. No.: US 2026/0105222 A1
(43) Pub. Date: Apr. 16, 2026

(54) EVALUATION OF INSTALLATION QUALITY OF ELEVATOR

(71) Applicant: KONE Corporation, Helsinki (FI)

(72) Inventors: Gabriela Roivainen, Helsinki (FI); Petri Kuisma, Helsinki (FI); Matti Lin, Helsinki (FI)

(73) Assignee: KONE Corporation, Helsinki (FI)

(21) Appl. No.: 19/361,567

(22) Filed: Oct. 17, 2025

Related U.S. Application Data
(63) Continuation of application No. PCT/FI2023/050263, filed on May 12, 2023.

(51) Int. Cl. G06F 30/27

(52) U.S. Cl. CPC G06F 30/27

(57) ABSTRACT

A method for generating data descriptive of a quality of an elevator installation is provided, the method is performed by an apparatus (170) configured to execute a machine learning-model trained with a simulation data, the method comprises: receiving (210) data descriptive of an operation of at least one entity of the installed elevator; inputting (220) the received data to the machine-learning model executed by the apparatus (170); setting (230), in accordance with an output from the machine-learning model, a detection result to express one of the following: (i) the quality of the elevator installation is acceptable (230A), (ii) the quality of the elevator installation is unacceptable (230B). An apparatus (170) and a computer program are also provided.

### TECHNICAL FIELD

The invention concerns in general the technical field of elevators. More particularly, the invention concerns evaluation of an installation of an elevator.

### BACKGROUND

Elevator installation is an operation comprising various tasks in order to maintain a safety in the operation of the elevator in all situations. Specifically speaking, the installation may refer to a situation in which the elevator is built up e.g. to a new building or it may refer to a situation in which one or more entities of the elevator is replaced in a context of maintenance operation conducted to the elevator system in question. The traditional way to arrange the installation in the described contexts is that the installation work is done and a technician performs the testing and/or checks in accordance with a testing plan. These measures are performed before the installation is accepted for normal operation and handed over from the installing party to the party managing it, such as a building manager. Even if the approach is operative as such it is vulnerable to mistakes performed by the technician e.g. in the testing procedure. Moreover, the known testing operations are quite simple as such.

Therefore, there is a need to introduce more sophisticated approaches for improving a quality of an elevator installation.

### SUMMARY

The following presents a simplified summary in order to provide basic understanding of some aspects of various invention embodiments. The summary is not an extensive overview of the invention. It is neither intended to identify key or critical elements of the invention nor to delineate the scope of the invention. The following summary merely presents some concepts of the invention in a simplified form as a prelude to a more detailed description of exemplifying embodiments of the invention.

An object of the invention is to present a method, an apparatus, and a computer program for generating data descriptive of a quality of an elevator installation.

The objects of the invention are reached by a method, an apparatus, and a computer program as defined by the respective independent claims.

According to a first aspect, a method for generating data descriptive of a quality of an elevator installation is provided, the method is performed by an apparatus configured to execute a machine learning-model trained with a simulation data of a simulation model corresponding to an installed elevator for evaluating the quality of the elevator installation, the method comprises:
receiving data descriptive of an operation of at least one entity of the installed elevator, the data is generated with a testing procedure of the at least one entity of the installed elevator,
inputting the received data to the machine-learning model executed by the apparatus,
setting, in accordance with an output from the machine-learning model, a detection result to express one of the following: (i) the quality of the elevator installation is acceptable, (ii) the quality of the elevator installation is unacceptable.

The data descriptive of the operation of the at least one entity of the installed elevator may be received from at least one of the following: a drive of an elevator door, an accelerometer associated to the elevator car, a magnetometer associated to the elevator car, a microphone, an image sensor, a depth sensor.

The method may further comprise:
generating, in response to the detection result is set to express that the quality of the elevator installation is unacceptable, a signal to a terminal device communicatively connected with the apparatus, the generated signal carrying data indicative of the detection result set to express that the quality of the elevator installation is unacceptable.

Moreover, the data carried in the generated signal may further define the at least one entity causing that the quality of the elevator installation is unacceptable. Also, the data carried in the generated signal may further define one or more instructions to overcome a situation expressing that the quality of the elevator installation is unacceptable.

Still further, the method may further comprise:
generating, in response to that the detection result is set to express that the quality of the elevator installation is acceptable, a quality report to a predefined entity, the quality report comprising data indicative of the detection result set to express that the quality of the elevator installation is acceptable.

According to a second aspect, an apparatus for generating data descriptive of a quality of an elevator installation is provided, the apparatus is configured to execute a machine learning-model trained with a simulation data of a simulation model corresponding to an installed elevator for evaluating the quality of the elevator installation, the apparatus is further configured to:
receive data descriptive of an operation of at least one entity of the installed elevator, the data is generated with a testing procedure of the at least one entity of the installed elevator,
input the received data to the machine-learning model executed by the apparatus,
set, in accordance with an output from the machine-learning model, a detection result to express one of the following: (i) the quality of the elevator installation is acceptable, (ii) the quality of the elevator installation is unacceptable.

The apparatus may be configured to receive the data descriptive of the operation of the at least one entity of the installed elevator from at least one of the following: a drive of an elevator door, an accelerometer associated to the elevator car, a magnetometer associated to the elevator car, a microphone, an image sensor, a depth sensor.

The apparatus may further be configured to:
generate, in response to the detection result is set to express that the quality of the elevator installation is unacceptable, a signal to a terminal device communicatively connected with the apparatus, the generated signal carrying data indicative of the detection result set to express that the quality of the elevator installation is unacceptable.

Moreover, the data carried in the generated signal may further define the at least one entity causing that the quality of the elevator installation is unacceptable. Also, the data carried in the generated signal may further define one or more instructions to overcome a situation expressing that the quality of the elevator installation is unacceptable.

Still further, the apparatus may further be configured to:
generate, in response to that the detection result is set to express that the quality of the elevator installation is acceptable, a quality report to a predefined entity, the quality report comprising data indicative of the detection result set to express that the quality of the elevator installation is acceptable.

According to a third aspect, a computer program is provided, the computer program comprising instructions to cause the apparatus of the second aspect as defined above to execute the steps of the method according to the first aspect as defined above.

The expression “a number of” refers herein to any positive integer starting from one, e.g. to one, two, or three.

The expression “a plurality of” refers herein to any positive integer starting from two, e.g. to two, three, or four.

Various exemplifying and non-limiting embodiments of the invention both as to constructions and to methods of operation, together with additional objects and advantages thereof, will be best understood from the following description of specific exemplifying and non-limiting embodiments when read in connection with the accompanying drawings.

The verbs “to comprise” and “to include” are used in this document as open limitations that neither exclude nor require the existence of unrecited features. The features recited in dependent claims are mutually freely combinable unless otherwise explicitly stated. Furthermore, it is to be understood that the use of “a” or “an”, i.e. a singular form, throughout this document does not exclude a plurality.

### BRIEF DESCRIPTION OF FIGURES

The embodiments of the invention are illustrated by way of example, and not by way of limitation, in the figures of the accompanying drawings.

FIG. 1 illustrates schematically a system according to an example.

FIG. 2 illustrates schematically a method according to an example.

FIG. 3 illustrates schematically a further aspect relating to the method according to an example.

FIG. 4 illustrates schematically another further aspect relating to the method according to an example.

FIG. 5 illustrates schematically an apparatus according to an example.

### DESCRIPTION OF THE EXEMPLIFYING EMBODIMENTS

The specific examples provided in the description given below should not be construed as limiting the scope and/or the applicability of the appended claims. Lists and groups of examples provided in the description given below are not exhaustive unless otherwise explicitly stated.

The present invention is for evaluating a quality of an elevator installation and the aim is to generate data descriptive on that. The elevator installation corresponds to a situation that a new elevator is built up and the aim is to take it into use. Additionally, it corresponds to a situation that a maintenance operation to an existing elevator is performed wherein the maintenance operation requires testing of the elevator in one or more predefined manner(s). The maintenance operation may refer to a replacement of one or more entities of the elevator which requires installation work comprising also any software installation or reinstallation together with any replacement of a physical part or system of the elevator. Any combination of the described elevator installations falls with the scope of the present invention.

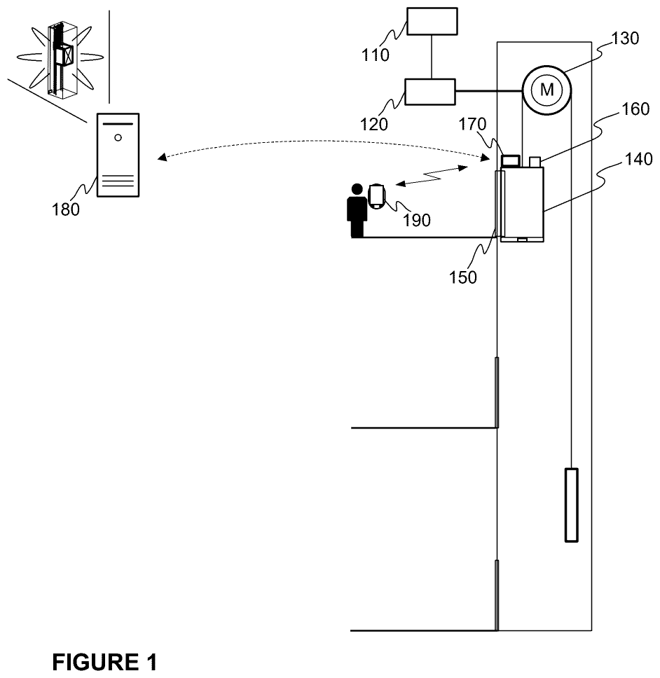

In the forthcoming description at least some aspects of the invention are described by referring to FIG. 1. FIG. 1 illustrates schematically at least some entities of a system according to an embodiment enabling an implementation of the invention as is described in the following. The system comprises an elevator system consisting of a plurality of entities to make it operative. FIG. 1 illustrates at least the following entities of the elevator system: an elevator controller 110, an elevator drive system, a traction sheave with electric motor 130, an elevator car 140, an elevator door system 150, a number of sensors 160. Additionally, FIG. 1 illustrates schematically an apparatus 170 that may be considered as an evaluation unit of data input to it. In the non-limiting example of FIG. 1 the apparatus 170 is associated to the elevator car 140, but it may reside in another location to the location shown in FIG. 1. Alternatively or in addition, a functionality of the apparatus 170 may be integrated, in at least some embodiments, to one or more other entities, such as to the elevator controller 110 or to an apparatus not physically associated to the elevator car 140, for instance.

Regarding the apparatus 170 it shall be considered as a computing device arranged to receive predefined type of data as an input. The data may e.g. refer to sensor data e.g. received from the sensor system 160 as a non-limiting example. The apparatus 170 may also comprise one or more internal sensors for gathering data to be analyzed with the apparatus 170 together with or instead to data from the sensor system 160. The apparatus 170 comprises a communication interface over which the apparatus 170 may be communicatively connected to other entities, such as to the sensor system 160 but also to other entities like to the elevator controller 110 or to the elevator drive 120 and so on. The communication technology used in the communication may be a wired communication technology or a wireless communication technology or any applicable combination of these as is known from prior art.

Furthermore, the apparatus 170 is configured to execute a machine learning-model trained with a simulation data of a simulation model which refers to a virtual elevator model, also callable as a digital twin, corresponding to the elevator under installation for evaluating the quality of the elevator installation. In other words, the simulation data may be generated with a computing system referred with 180 in FIG. 1 which is configured to simulate an operation of the elevator with the simulation model in a various manner. The simulation model shall be understood herein to correspond to the elevator under installation at a predefined accuracy. The accuracy may be defined at an entire elevator system level or at an entity level in accordance with the installation operation performed to the elevator in question. The accuracy may e.g. be at a level that the simulation model exactly corresponds the elevator under installation or it may belong to a same product line and so on. In any approach the simulation model shall be such that the simulation data generated with the simulation model is applicable in the context of the elevator under installation at a required level. As regards to the simulation, the simulation model is executed with various input parameters and in any other manner so as to generate training data to train the machine-learning model executed by the apparatus 170 in its operation. For example, the simulation data may be generated so that the simulation model is executed with parameters causing the simulation model to follow a normal operation of the elevator. Additionally, the simulation model may be executed with parameters causing the simulation model to end up various error situations which may be considered as a malfunctioning of the elevator corresponding to the simulation model. Thus, the training data generated by simulating the simulation model may be considered to comprise data, which is descriptive of an acceptable operation of the elevator, and data, which is descriptive of an unacceptable operation of the elevator. In some embodiments the training data may only define one of the mentioned operations, i.e. that the training data is descriptive of the acceptable operation of the elevator or that the data is descriptive of the unacceptable operation of the elevator. In such an approach the executing entity of the machine-learning model may be configured to execute so that if the trained machine-learning model does not detect the state, i.e. the operation type of the elevator, it is trained to detect, it may conclude that it generates an outcome indicative of the other state (cf. acceptable operation/unacceptable operation).

The training of the machine-learning model may be executed in the computing system 180 with the generated training data. In response to the training the trained machine-learning model may be transferred to the apparatus 170 for execution in the site. The transfer of the trained simulation model to the apparatus 170 may be arranged over an applied communication channel or by transferring the model with a medium suitable to store data for the purpose wherein the medium may e.g. be a transferable data storage, such as a memory stick. Alternatively or in addition, the training of the machine-learning model may be performed in the apparatus 170 so that the training data from the computing system 180 is conveyed therein and the training is executed by the apparatus 170. As is derivable from above the machine-learning model may be trained to execute a classification task to the data input to it in order to decide if—based on the data input to the machine-learning model—the elevator operates in an acceptable manner or in an unacceptable manner.

Depending on the implementation of the machine-learning model and a format of the training data the machine-learning model may also be configured to output, in addition to the above-described detection result, data identifying at least one entity of the elevator causing the detection result to correspond to the unacceptable operation of the elevator. Such an approach may require that the training data also defines an entity causing the detection result descriptive of the unacceptable operation of the elevator, which is then in the internal operation of the machine-learning model also generated as an output e.g. together with the detection result or integrated to the detection result. Naturally, corresponding additional data may also be generated, or associated to, in a situation that the elevator is detected to operate in an acceptable way.

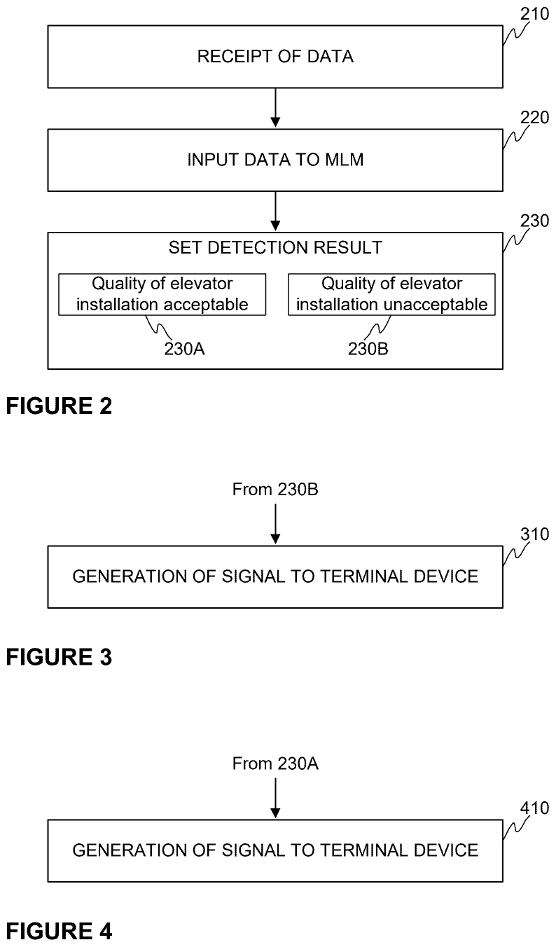

From an operative point of view the apparatus 170, or another suitable entity, may be arranged at least to perform the method as schematically illustrated in FIG. 2 by applying the machine-learning model trained as described in the method in the manner as is brought out in the forthcoming description. By executing the method data descriptive of a quality of an elevator installation may be generated. First, in a step denoted with 210 in FIG. 2 data descriptive of an operation of at least one entity of the installed elevator is received 210. In other words, the data descriptive of the operation of the at least one entity may refer to data obtained from the sensor system 160 with one or more sensors and the data may represent an overall operation of the elevator under installation or an operation of one or more predefined entities of the elevator. Alternatively, the data may be received 210 by obtaining predefined operational parameters from the elevator, such as control signal data from the elevator drive 120, or similar. Specifically speaking, the data received by the apparatus 170 is generated with a testing procedure of the at least one entity of the installed elevator. This refers to that due to the installation work the elevator, or at least one relevant entity of the elevator, is tested in a predefined manner in accordance with the installation task performed to the elevator. The testing procedure may e.g. correspond to a test drive of the elevator, i.e. the elevator car 140 is caused to travel in its path in a predefined manner according to a testing plan. Moreover, the testing plan may correspond to operating the one or more predefined entities and monitor their operation e.g. with the sensors. For example, if the installation has related to a replacement of elevator door(s) (cf. landing doors and/or elevator car doors), the testing procedure may comprise causing the elevator doors to open and to close a predefined number of times e.g. in one or more floors and data e.g. from a door drive is received by the apparatus 170. For sake of completeness it is worthwhile to mention that the sensors applied in the context of the present invention may be different types, such as accelerometers or magnetometers associated to moving parts of the elevator system, such as to the elevator car 140. Further examples of applicable sensors may be microphones, image sensors, depth sensors which may be used for capturing various types of data descriptive of an operation of the at least one entity of the installed elevator, such as indicating a gap between two or more entities of the elevator. With the various arrangements of generating the data delivered to the apparatus 170 an operational condition of a plurality of entities of the elevator may be evaluated. For example, such operational conditions may e.g. to one of the following aspects: each landing door roller misalignments, door lock clearance, guide rails misalignments, mechanical shortcuts between car and pulley beam, mechanical shortcuts between machinery and guide rails, wrongly installed guide shoes or guide rails (without continuous lubrification) and so on. In the foregoing description it is mainly described that the data is received from the sensor system 160 by the apparatus 170, but as mentioned the source of data may differ from the sensor system 160. Furthermore, the apparatus 170 may be configured to receive the data directly from the respective source(s) or through another entity, such as through the elevator controller 110 or similar. Thus, the testing procedure may be controlled either directly or indirectly from the apparatus 170, or it may e.g. be triggered by the elevator controller 110 which is configured to gather the data and deliver it to the apparatus 170, for example.

In response to the receipt of the data obtainable e.g. in accordance with a predefined testing procedure executed by the installed elevator the received data is input 220 to the machine-learning model executed by the apparatus 170. The machine-learning model is configured to output by evaluating the data input 220 to it a detection result to express if the elevator, based on the received data, operates as expected or not. Hence, in accordance with the output from the machine-learning model the apparatus 170 is configured to set 230 a detection result to express one of the following: (i) the quality of the elevator installation is acceptable 230A, (ii) the quality of the elevator installation is unacceptable 230B. The generation of the data descriptive of the quality of the elevator installation in the manner as described in the foregoing description may be continued as schematically illustrated in FIG. 3. Namely, in response to a detection that the detection result is set to express that the quality of the elevator installation is unacceptable 230B a signal to a terminal device 190 communicatively connected with the apparatus 170 may be generated 310. The generated signal may be included with data indicative of the detection result set to express that the quality of the elevator installation is unacceptable 230B. The terminal device 190 herein may refer to a terminal device of a technician e.g. residing in the site the elevator is installed to. For example, the technician may be the one who has performed the installation task and who has triggered the testing procedure of the at least one entity of the elevator. Thus, in response to the generation 310 of the signal to the terminal device a result in a case of the unacceptable quality of the installation may be delivered to the technician. The communication connection may be implemented with an appropriate communication technology, such as a wireless near-field communication technology like Wi-Fi or Bluetooth.

In accordance with an embodiment of the invention the signal generated in the step 310 of FIG. 3 it may also carry data that further defines the at least one entity causing that the quality of the elevator installation is unacceptable 230B. This kind of embodiment may be implemented so that the machine-learning model is also trained to return data indicative of the one or more entities causing the unacceptable 230B quality of the elevator installation which piece of information is then delivered to the terminal device 190 by the apparatus 170. The terminal device 190 may then output the information to the technician which helps the technician to take necessary measures with respect to the root cause of the detection result indicating the unacceptable 230B quality in the installation. In some further embodiments the delivered data may also comprise one or more instructions to overcome a situation expressing that the quality of the elevator installation is unacceptable, such as describing necessary tasks the technician shall take in order to overcome the unacceptable quality. The data may also be provided by the machine-learning model when trained to do so or it may be included by the apparatus 170 to the signal delivered to the terminal device 190. The apparatus 170 may e.g. store such data in an internal memory or it may inquire it from an external memory into which it is arranged with an access. In case the data is acquired from the memory the machine-learning model may be arranged to return data descriptive of the data to be acquired from the memory, such as an indicator value of the data or a memory address or a network address to such data. Further option to arrange the technician to access the data may be that the apparatus 170 is configured to include a network address to the signal delivered to the terminal device 190 so as to enable the technician to access the data in an easy manner.

Also in a situation that the detection result expresses an acceptable quality of the elevator installation the apparatus 170 may be configured to perform further operations. Such a method step is schematically illustrated in FIG. 4. Namely, in accordance with an embodiment the apparatus 170 may be configured to generate 410, in response to that the detection result is set to express that the quality of the elevator installation is acceptable, a quality report to a predefined entity. The predefined entity may e.g. be the terminal device 190 of a technician or a computing entity of a maintenance company performing the installation task or a computing entity of a party owning the elevator under installation, or any combination of these. The quality report may comprise data descriptive of the testing procedure, such as any analysis result of the data received, but also the original data, for example. This kind of approach enables an appropriate documentation of the elevator installation procedure for any further use, such as for verification when necessary.

It is also worth mentioning that the invention according to some embodiments may be configured to perform only one of the method steps disclosed in FIGS. 3 and 4, or both of them dependently on the detection result.

As already mentioned, the apparatus 170 configured to perform the method may be a device associable to the elevator, such as to the elevator car 140 as already mentioned. In some other embodiments the functionality of the apparatus 170 as described may be integrated to another entity, such as one belonging to the elevator system. A non-limiting example of the other entity may e.g. be the elevator controller 110.

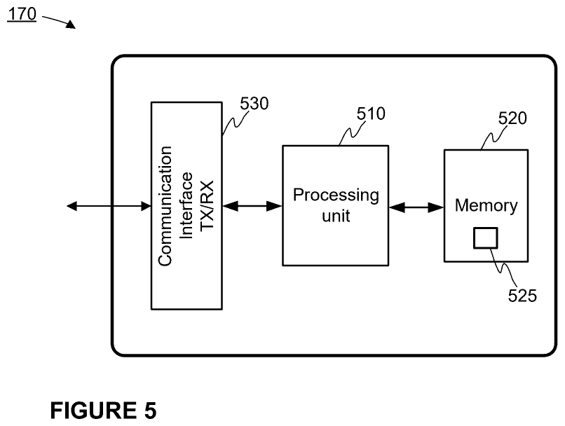

An example of an apparatus suitable to execute the method is schematically illustrated in FIG. 5. Thus, the apparatus of FIG. 5 may be configured to perform a generation of data descriptive of a quality of an elevator installation. For sake of clarity, it is worthwhile to mention that the block diagram of FIG. 5 depicts some components of an entity that may be employed to implement a functionality of the apparatus 170. The apparatus of FIG. 5 comprises a processor 510 and a memory 520. The memory 520 may store data, such as pieces of data as described, but also computer program code 525 causing the operation in the described manner. The apparatus may further comprise a communication interface 530, such as a wireless communication interface or a communication interface for wired communication, or both to communicate with other entities as described. The communication interface 530 may thus comprise one or more modems, antennas, and any other hardware and software for enabling an execution of the communication e.g. under control of the processor 510. Furthermore, I/O (input/output) components may be arranged, together with the processor 510 and a portion of the computer program code 525, to provide a user interface for receiving input from a user, such as from a technician, and/or providing output to the user of the apparatus when necessary. In particular, the I/O components may include user input means, such as one or more keys or buttons, a keyboard, a touchscreen, or a touchpad, etc. The I/O components may include output means, such as a loudspeaker, a display, or a touchscreen. The components of the apparatus 170 may be communicatively connected to each other via data bus that enables transfer of data and control information between the components.

The memory 520 and at least a portion of the computer program code 525 stored therein may further be arranged, with the processor 510, to cause the apparatus to perform at least a portion of a method as is described herein. The processor 510 may be configured to read from and write to the memory 520. Although the processor 510 is depicted as a respective single component, it may be implemented as respective one or more separate processing components. Similarly, although the memory 520 is depicted as a respective single component, it may be implemented as respective one or more separate components, some, or all of which may be integrated/removable and/or may provide permanent/semi-permanent/dynamic/cached storage.

The computer program code 525 may comprise computer-executable instructions that implement functions that correspond to steps implemented in the method when loaded into the processor 510 of the respective apparatus 170. As an example, the computer program code 525 may include a computer program consisting of one or more sequences of one or more instructions. The processor 510 is able to load and execute the computer program by reading the one or more sequences of one or more instructions included therein from the memory 520. The one or more sequences of one or more instructions may be configured to, when executed by the processor 510, cause the apparatus, such as a computer, to perform a method as described. Hence, the apparatus may comprise at least one processor 510 and at least one memory 520 including the computer program code 525 for one or more programs, the at least one memory 520 and the computer program code 525 configured to, with the at least one processor 510, cause the apparatus to perform the method.

The computer program code 525, or at least some portion of it, may be provided e.g. a computer program product comprising at least one computer-readable non-transitory medium having the computer program code 525 stored thereon, which computer program code 525, when executed by the processor 510 causes the apparatus to perform the method. The computer-readable non-transitory medium may comprise a memory device or a record medium, such as a CD-ROM, a DVD, a Blu-ray disc, or another article of manufacture that tangibly embodies the computer program. As another example, the computer program may be provided as a signal configured to reliably transfer the computer program.

Still further, the computer program code 525 may comprise a proprietary application, such as computer program code for causing an execution of the method in the manner as described in the description herein.

Any of the programmed functions mentioned may also be performed in firmware or hardware adapted to or programmed to perform the necessary tasks.

For sake of completeness it is worthwhile to mention that the entity performing the method in the role of the apparatus 170 may also be implemented with a plurality of apparatuses, such as the one schematically illustrated in FIG. 5, as a distributed computing environment corresponding to an apparatus. For example, one of the apparatuses may be communicatively connected with the other apparatuses, and e.g. share the data of the method, to cause another apparatus to perform at least one other portion of the method. As a result, the method performed in the distributed computing environment generates the control signal indicative of the assignment of the responsibility as described.

The specific examples provided in the description given above should not be construed as limiting the applicability and/or the interpretation of the appended claims. Lists and groups of examples provided in the description given above are not exhaustive unless otherwise explicitly stated.

1. A method for generating data descriptive of a quality of an elevator installation, the method is performed by an apparatus configured to execute a machine learning-model trained with a simulation data of a simulation model corresponding to an installed elevator for evaluating the quality of the elevator installation, the method comprises: receiving data descriptive of an operation of at least one entity of the installed elevator, the data is generated with a testing procedure of the at least one entity of the installed elevator, inputting the received data to the machine-learning model executed by the apparatus, setting, in accordance with an output from the machine-learning model, a detection result to express one of the following: (i) the quality of the elevator installation is acceptable, (ii) the quality of the elevator installation is unacceptable

2. The method according to claim 1, wherein the data descriptive of the operation of the at least one entity of the installed elevator is received from at least one of the following: a drive of an elevator door, an accelerometer associated to the elevator car, a magnetometer associated to the elevator car, a microphone, an image sensor, a depth sensor.

3. The method according to claim 1, the method further comprises:
generating, in response to the detection result is set to express that the quality of the elevator installation is unacceptable, a signal to a terminal device communicatively connected with the apparatus, the generated signal carrying data indicative of the detection result set to express that the quality of the elevator installation is unacceptable.

4. The method according to claim 3, wherein the data carried in the generated signal further defines the at least one entity causing that the quality of the elevator installation is unacceptable.

5. The method according to claim 4, wherein the data carried in the generated signal further defines one or more instructions to overcome a situation expressing that the quality of the elevator installation is unacceptable.

6. The method according to claim 1, the method further comprises:
generating, in response to that the detection result is set to express that the quality of the elevator installation is acceptable, a quality report to a predefined entity, the quality report comprising data indicative of the detection result set to express that the quality of the elevator installation is acceptable.

7. An apparatus for generating data descriptive of a quality of an elevator installation, the apparatus configured to execute a machine learning-model trained with a simulation data of a simulation model corresponding to an installed elevator for evaluating the quality of the elevator installation, the apparatus is further configured to:
receive data descriptive of an operation of at least one entity of the installed elevator, the data is generated with a testing procedure of the at least one entity of the installed elevator, input the received data to the machine-learning model executed by the apparatus, set, in accordance with an output from the machine-learning model, a detection result to express one of the following: (i) the quality of the elevator installation is acceptable, (ii) the quality of the elevator installation is unacceptable.

8. The apparatus according to claim 7, wherein the apparatus is configured to receive the data descriptive of the operation of the at least one entity of the installed elevator from at least one of the following: a drive of an elevator door, an accelerometer associated to the elevator car, a magnetometer associated to the elevator car, a microphone, an image sensor, a depth sensor.

9. The apparatus according to claim 7, the apparatus is further configured to:
generate, in response to the detection result is set to express that the quality of the elevator installation is unacceptable, a signal to a terminal device communicatively connected with the apparatus, the generated signal carrying data indicative of the detection result set to express that the quality of the elevator installation is unacceptable.

10. The apparatus according to claim 9, wherein the data carried in the generated signal further defines the at least one entity causing that the quality of the elevator installation is unacceptable.

11. The apparatus according to claim 10, wherein the data carried in the generated signal further defines one or more instructions to overcome a situation expressing that the quality of the elevator installation is unacceptable.

12. The apparatus according to claim 7, the apparatus further configured to:
generate, in response to that the detection result is set to express that the quality of the elevator installation is acceptable, a quality report to a predefined entity, the quality report comprising data indicative of the detection result set to express that the quality of the elevator installation is acceptable.

13. A non-transitory computer readable medium storing a computer program comprising instructions to cause an apparatus to execute the steps of the method of claim 1.

14. The method according to claim 2, the method further comprises:
generating, in response to the detection result is set to express that the quality of the elevator installation is unacceptable, a signal to a terminal device communicatively connected with the apparatus, the generated signal carrying data indicative of the detection result set to express that the quality of the elevator installation is unacceptable.

15. The method according to claim 2, the method further comprises:
generating, in response to that the detection result is set to express that the quality of the elevator installation is acceptable, a quality report to a predefined entity, the quality report comprising data indicative of the detection result set to express that the quality of the elevator installation is acceptable.

16. The method according to claim 3, the method further comprises:
generating, in response to that the detection result is set to express that the quality of the elevator installation is acceptable, a quality report to a predefined entity, the quality report comprising data indicative of the detection result set to express that the quality of the elevator installation is acceptable.

17. The method according to claim 4, the method further comprises:
generating, in response to that the detection result is set to express that the quality of the elevator installation is acceptable, a quality report to a predefined entity, the quality report comprising data indicative of the detection result set to express that the quality of the elevator installation is acceptable.

18. The method according to claim 5, the method further comprises:
generating, in response to that the detection result is set to express that the quality of the elevator installation is acceptable, a quality report to a predefined entity, the quality report comprising data indicative of the detection result set to express that the quality of the elevator installation is acceptable.

19. The apparatus according to claim 8, the apparatus is further configured to:
generate, in response to the detection result is set to express that the quality of the elevator installation is unacceptable, a signal to a terminal device communicatively connected with the apparatus, the generated signal carrying data indicative of the detection result set to express that the quality of the elevator installation is unacceptable.

20. The apparatus according to claim 8, the apparatus further configured to:
generate, in response to that the detection result is set to express that the quality of the elevator installation is acceptable, a quality report to a predefined entity, the quality report comprising data indicative of the detection result set to express that the quality of the elevator installation is acceptable.
